(19) United States
(12) Patent Application Publication
(10) Pub. No.: US 2023/0378364 A1
(43) Pub. Date: Nov. 23, 2023

(54) 3D DESIGN WITH METHOD OF INTEGRATION OF HIGH PERFORMANCE TRANSISTORS USING A STREAMLINED PROCESS FLOW

(71) Applicant: Tokyo Electron Limited, Tokyo (JP)

(72) Inventors: H. Jim Fulford, Albany, NY (US); Mark I. Gardner, Albany, NY (US); Partha Mukhopadhyay, Albany, NY (US)

(21) Appl. No.: 17/749,957

(22) Filed: May 20, 2022

(51) Int. Cl. H01L 29/786; H01L 29/417; H01L 29/66; H01L 21/8234; H01L 27/088

(52) U.S. Cl. CPC H01L 29/78618; H01L 29/78696; H01L 29/41733; H01L 29/66742; H01L 21/823412; H01L 21/823418; H01L 27/0886

(57) ABSTRACT

Structures and methods of semiconductor transistor structure include a first source/drain contact of a transistor and a dielectric structure formed on top of the first source/drain contact. A gate electrode of the transistor can be formed on top of the dielectric structure. A gate dielectric can include a first part formed vertically along at least a first sidewall of the gate electrode and a second part formed vertically along at least a second sidewall of the gate electrode. A channel of the transistor can include a first part formed on a surface of the first part of the gate dielectric and a second part formed on a surface of the second part of the gate dielectric. A second source/drain contact of the transistor can include a first part on top of the first part of the channel and a second part on top of the second part of the channel.

### TECHNICAL FIELD

This disclosure related to microelectronic devices including semiconductor device, transistors, and integrated circuits, including methods of microfabrication.

### BACKGROUND

Fabrication of semiconductor devices relies on execution of various fabrication processes, such as film-forming depositions, doping treatments, etch mask creation, patterning, material etching, and removal. These processes are performed repeatedly in order to form desired semiconductor features on a substrate. Historically, with microfabrication of semiconductor devices, transistors have been created in one plane, while wiring and metallization features were formed above the active device plane, thereby resulting in what has been characterized as two-dimensional (2D) circuits or 2D fabrication. While for many years scaling efforts have increased the number of transistors per unit area in 2D circuits, in more recent years, scaling challenges have emerged as semiconductor device features approached single digit nanometer fabrication nodes. Semiconductor device fabricators have expressed a desire to find new ways to overcome the scaling challenges.

### SUMMARY

When scaling semiconductor devices to feature sizes that are only several atoms thick, fabricators of integrated circuits (“IC”) have been increasingly encountering technical issues, such as leakage currents and short-channel effects. It has been observed that the smaller the space between active features of a semiconductor device, the more pronounced these technical issues can be. The present disclosure provides solutions that overcomes these issues by providing three-dimensional (3D) semiconductor circuits in which transistors are stacked on top of each other, thereby allowing for improved scaling (i.e., more circuits per unit area) while also preventing or limiting leakage currents, short channel effects. The present solution provides 3D integrated semiconductor devices can help overcome scaling limitations experienced in planar devices by increasing transistor density in volume rather than area.

Although some device stacking has been demonstrated and implemented by the flash memory industry with the adoption of 3D NAND semiconductor designs, the application of this technology to other logic designs and circuits is substantially more difficult and complex. A part of the challenge relates to the fact that 3D semiconductor fabrication processes can be intricate and use many masks and process steps in order to complete the 3D semiconductor devices, which adds to the complexity and cost of the fabrication process while also reducing fabrication yield. Another part of the challenge is the difficulty in forming electrical contacts between semiconductor devices in 3D stacked devices. The present solution allows for fabrication of single-node and double-node 3D semiconductor devices that can be produced using a simple fabrication process that can rely on as few as only three lithography masks, which allows for a simpler and more efficient 3D semiconductor fabrication and interconnection, both laterally and vertically, between various 3D stacked transistor devices. The present solution can also provide an architecture and methodology for building logic and memory vertical field-effect transistor (VFET) structures that utilize self-aligned processing techniques to help fabricate 3D VFET arrays with a reduced usage of masks.

The present solution relates to a semiconductor transistor structure. The semiconductor transistor structure can include a transistor. The transistor can include a first source/drain contact of a transistor. The transistor can include a dielectric structure formed on top of the first source/drain contact and a gate electrode of the transistor formed on top of the dielectric structure. The transistor can include a gate dielectric. The gate dielectric can include a first part formed vertically along at least a first sidewall of the gate electrode and a second part formed vertically along at least a second sidewall of the gate electrode. The transistor can include a channel that can include a first part formed on a surface of the first part of the gate dielectric and a second part formed on a surface of the second part of the gate dielectric. The transistor can include a second source/drain contact of the transistor comprising a first part on top of the first part of the channel and a second part on top of the second part of the channel.

The semiconductor transistor structure can include the gate electrode that extends vertically above the dielectric structure. The height of the gate electrode can be greater than each of a width and a thickness of the gate electrode. The semiconductor transistor structure can include the first part of the channel and the second part of the channel each including a conductive oxide material. The conductive oxide material can abut the gate dielectric and extend vertically along the gate electrode. The semiconductor transistor structure can include (i) the first part of the gate dielectric further extending along a first sidewall of the dielectric structure and (ii) the second part of the gate dielectric further extending along a second sidewall of the dielectric structure.

The semiconductor transistor structure can include a gate contact formed on top of the gate electrode and at a same height (e.g., in the same horizontal plane) as the first and second parts of the second source/drain contacts. The semiconductor transistor structure can include a dielectric material layer insulating the first source/drain contact from a substrate beneath the first source/drain contact. The semiconductor transistor structure can include the gate dielectric further including a third part between a top surface of the dielectric structure and a bottom surface of the gate electrode.

The semiconductor transistor structure can include the channel that includes a bottom surface of the first part in contact with the first source/drain contact and a bottom surface of the second part in contact with the first source/drain contact. The semiconductor transistor structure can include a first source/drain contact of a second transistor formed above a layer of dielectric material that is formed above the first and the second parts of the second source/drain contact. The semiconductor transistor structure can include a dielectric structure of the second transistor formed on top of the first source/drain contact of the second transistor. The semiconductor transistor structure can include a gate electrode of the second transistor formed on top of the dielectric structure of the second transistor. The semiconductor transistor structure can include a gate dielectric of the second transistor comprising a first part formed vertically along at least a first sidewall of the gate electrode of the second transistor and a second part formed vertically along at least a second sidewall of the gate electrode of the second transistor. The semiconductor transistor structure can include a channel of the second transistor. The channel of the second transistor can include a first part formed on a surface of the first part of the gate dielectric of the second transistor and a second part formed on a surface of the second part of the gate dielectric of the second transistor. The semiconductor transistor structure can include a second source/drain contact of the second transistor having a first part on top of the first part of the channel of the second transistor and a second part on top of the second part of the channel of the second transistor.

The semiconductor transistor structure can include the layer of dielectric material formed above the first and the second parts of the second source/drain contact and below the second transistor. The semiconductor transistor structure can include the layer of dielectric material including a routing layer that can include one or more metal connections for routing electrical signals to one or more of the transistor or the second transistor.

The present solution relates to a method of forming a transistor structure. The method can include forming a first source/drain contact of a transistor. The method can include forming a dielectric structure on top of the first source/drain contact. A gate electrode of the transistor may be formed on top of the dielectric structure. A first part of a gate dielectric may be formed vertically along at least a first sidewall of the gate electrode and a second part of the gate dielectric may be formed vertically along at least a second sidewall of the gate electrode. A first part of a channel of the transistor may be formed on a surface of the first part of the gate dielectric and a second part of the channel of the transistor may be formed on a surface of the second part of the gate dielectric. The method can include forming a first part of a second source/gate structure of the transistor on top of the first part of the channel and forming a second part of the second source/gate structure of the transistor on top of the second part of the channel.

The method can further include forming the gate electrode includes vertically extending the first part of the gate electrode above the dielectric structure, the height of the gate electrode being greater than each one of a width and a thickness of the gate electrode. The first part of the channel and the second part of the channel may be formed with a respective conductive oxide material abutting the gate dielectric and extending vertically along the gate electrode.

The first part of the gate dielectric may be formed by further including extending the first part of the gate dielectric along a first sidewall of the dielectric structure and forming the second part of the gate dielectric further including extending the second part of the gate dielectric along a second sidewall of the dielectric structure. A gate contact may be formed on top of the gate electrode, where the gate contact may be formed at a same height as the first and second parts of the second source/drain contacts.

The method can include forming a dielectric material layer insulating the first source/drain contact from a substrate beneath the first source/drain contact. The method can include forming a third part of the gate dielectric between a top surface of the dielectric structure and a bottom surface of the gate electrode. The method can include forming a bottom surface of the first part of the channel in contact with the first source/drain contact. The method can include forming a bottom surface of the second part of the channel in contact with the first source/drain contact.

The method can include forming a first source/drain contact of a second transistor above the first and second parts of the second source/drain contact. The method can include forming a dielectric structure of the second transistor on top of the first source/drain contact of the second transistor. The method can include forming a gate electrode of the second transistor on top of the dielectric structure of the second transistor. The method can include forming a first part of a gate dielectric of the second transistor along at least a first sidewall of the gate electrode of the second transistor. The method can include forming a second part of the gate dielectric of the second transistor along at least a second sidewall of the gate electrode of the second transistor. The method can include forming a first part of a channel of the second transistor on a surface of the first part of the gate dielectric of the second transistor. The method can include forming a second part of the channel of the second transistor on a surface of the second part of the gate dielectric of the second transistor. The method can include forming a first part of the second source/gate contact of the second transistor on top of the first part of the channel of the second transistor. The method can include forming a second part of the second source/gate contact of the second transistor on top of the second part of the channel of the second transistor.

The method can include forming, above the first and the second parts of the second source/drain contact and below the second transistor, a routing layer comprising one or more metal connections for routing electrical signals to one or more of the transistor or the second transistor.

These and other aspects and implementations are described in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the present disclosure can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing.

FIGS. 1-18 illustrate cross-sectional and top-down illustrations of a fabrication flow for manufacturing a transistor structure with one or more double-node vertical transistors fabricated using 3D VFET fabrication techniques, according to one or more embodiments.

FIG. 19 illustrates cross-sectional and perspective views of a fabrication flow and structure utilizing 3D VFET hierarchical stackable fabrication techniques, according to one or more embodiments.

FIGS. 20-24 illustrate cross-sectional and top-down illustrations of a fabrication flow for manufacturing a transistor structure with one or more single-node vertical transistors fabricated using 3D VFET fabrication techniques, according to one or more embodiments.

FIG. 25 illustrates a flow diagram of a method for fabricating the structures using 3D VFET fabrication techniques discussed in connection with FIGS. 1-24, according to one or more embodiments.

### DETAILED DESCRIPTION

Reference will now be made to various illustrative embodiments depicted in the drawings, and specific language will be used to describe the same. It will nevertheless be understood that no limitation of the scope of the claims or this disclosure is thereby intended. Alterations and further modifications of the inventive features illustrated herein, and additional applications of the principles of the subject matter illustrated herein, which would be apparent to one of ordinary skill in the relevant art having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

It is understood that apparatuses, systems and devices produced by the structures described herein can be used or find their application in any number of electronic devices utilizing structures and/or circuits described herein, such as for example, controllers, memory chips, systems or process on a chip processors, graphics processing units, central processing units and more. For example, structures and/or circuits described herein can include a part of systems including or utilizing memory, such as any computing systems including for example: computers, phones, servers, cloud computing devices, and any other device or system that utilizes integrated circuit devices.

The embodiments described herein may enable an increased stack height of one or more 3D semiconductor devices. Therefore, a semiconductor substrate can be used, but is not required, and any base layer material (e.g., glass, organic, etc.) may be used instead of a silicon substrate. A base layer, therefore, can be a semiconductor substrate, such as a silicon substrate or any other semiconductor, ceramic, metal or other material substrate.

The process flows described herein can utilize conductive dielectric materials to form NMOS and PMOS devices. As such, the techniques described herein can be used to produce devices that are manufactured, or “stacked” on any existing vertically stacked device or substrate, according to various implementations. The present techniques may improve upon other semiconductor manufacturing techniques by increasing the N height of stacked semiconductor devices, such as transistors, thereby providing high density logic. Although illustrations herein may show an NMOS device arranged over a PMOS device, alternative configurations may include a PMOS device over NMOS device, NMOS device over NMOS device, PMOS device over PMOS device, or other alternative including one or more NMOS devices or PMOS devices for any number of N stacks and in any order or arrangement.

Dielectric materials used herein can be any material or materials having low electrical conductivity, such as for example one millionth of a mho/cm. Dielectric materials can include, for example, silicon dioxide, silicon nitride, nanoporous silica, hydrogensilsesquioxanes (HSQ), Teflon-AF (Polytetrafuoethene or PTFE), Silicon Oxyflouride. Dielectric materials can also include, for example, ceramics, glass, mica, organic and oxides of various metals.

High-k dielectric, also referred to as high-k material, can refer to any material with a higher dielectric constant as compared to the silicon dioxide. For example, high-k dielectric can include hafnium silicate, zirconium silicate, hafnium dioxide, zirconium dioxide, and others.

Various metals, such as gate metal and the source/drain metal, can be used herein and can include any metal or any electrically conductive material. For example, metals used in the present solution can include aluminum, copper, titanium, ruthenium, titanium, tungsten, silver, gold or any other metal. For the purposes of the present solution, in addition to the metals, source/drain metals or gate metals can also include other electrically conductive materials, such as highly doped semiconductors, for example.

The present solution can also utilize 2D materials for forming transistor channels. 2D materials can include, for example, but are not limited to, WS2, WSe2, WTe2, MoS2, MoSe2, MoTe2, HfS2, ZrS2, and TiS2, GaSe, InSe, phosphorene, and other similar materials. These materials can be deposited by an atomic layer deposition (ALD) process and may be about 5-15 angstroms thick, the thinness lending to their name—2D material. 2D material layer can, depending on the material and design, and can have a broader range of thicknesses, such as between 0.2 nm and 3 nm, for example. 2D materials may be annealed during or after the device formation process to recrystallize or grow the crystals and thereby improve electrical characteristics. 2D materials, for example, can be electrically conductive.

Additionally or alternatively, 2D materials to be used for forming 2D channels may comprise one or more semiconductive-behaving materials, which may be formed using certain elements that, when combined with oxygen, form a new material that exhibits semiconductive behavior. For example, the semiconductive behaving material can be “turned off” and can have a low or practically no off-state leakage current, and can be “turned on” and become highly conductive when voltage is applied. Example materials to create an n-type channel for example include, but are not limited to, In2O3, SnO2, In GaZnO, and ZnO. Example materials that can be used to create a p-type channel may be formed utilizing, for example, SnO. These materials may be further doped to improve the electrical characteristics. These materials may also be referred to as conductive oxides or semiconductive behaving oxides for the purposes of this discussion.

As 2D materials can have a very large mobility, the 2D materials can be herein described as one embodiment. However, it is to be appreciated that other non-epitaxially grown materials can be utilized. Because a 2D material can be precisely deposited on an insulative sheet, this can enable a very low Dt integration build of horizontal nanosheets with high performance. Advantageously, any base substrate material can be utilized as no epitaxial growth is required and the base substrate can be removed for further stacking of the devices.

Carrier nanosheets can be used to provide support for the 2D material layers. Carrier nanosheets can include dielectric materials or semiconductor materials on which 2D material layer, such as a monolayer of 2D material, can be deposited, grown or otherwise formed. Carrier nanosheet can include an electrically insulating material that can be used as a seed layer for the 2D material(s) used in the stack. Additionally or alternatively, a seed layer can include a material that can be deposited onto a carrier nanosheet and onto which a layer of 2D material can be formed, deposited or applied.

The present disclosure can also refer to conductive oxide materials. Conductive oxides can include certain types of materials that include elements combined with oxygen to form a new material that exhibits semiconductor properties, including being able to turn off with low off state leakage current under some conditions and be highly conductive under other conditions. For example, N type conductive channels can be formed with In2O3, SnO2, InGaZnO and ZnO. P type conductive channels can be formed with SnO. Using these materials, N-type and P-type transistors can be formed using conductive oxides. In some instances, conductive oxides can be used instead of or together with 2D materials, and vice versa.

The order of description or fabrication steps performed or described herein has been presented for clarity sake and as an example. The fabrication steps described herein can be performed in any suitable order. Additionally, although each of the different features, techniques, configurations described herein may be described in different places of this disclosure, it is intended that each of the concepts can be executed independently of each other or in combination with each other. Accordingly, the solutions described herein can be embodied and viewed in many different ways.

Reference will now be made to the Figures, which for the convenience of visualizing the 3D semiconductor fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections, and they should not be considered limiting to the scope of the claims. Conversely, when example illustrations do not show electrical connections to components that are electrically contacted, it is understood that such electrical connections can be made as understood by a person of ordinary skill.

Although the Figures and aspects of the disclosure may show or describe devices herein as having a particular shape, it should be understood that such shapes, whether of the structures or features, are used as examples of the present solution and are merely illustrative and should not be considered limiting to the scope of the techniques described herein. For example, although most of the Figures show various layers in a rectangular shaped configuration, other shapes are also contemplated, and indeed the techniques described herein may be implemented in any shape or geometry. In addition, examples in which two transistors or devices are shown stacked on top of one another are shown for illustrative purposes only, and for the purposes of simplicity. Indeed, the techniques described herein may provide for one to any number N stacked devices. Further, although the devices fabricated using these techniques are shown as transistors, it should be understood that any type of electronic device may be manufactured using such techniques, including but not limited to transistors, variable resistors, resistors, capacitors, memory components, logic gates and components and any other components known or used in the art.

Despite the fact that illustrated embodiments for simplicity and brevity show examples of only a single or double transistor structures being formed using the techniques of the present solution, any number of transistors can be formed above and beside the transistor structures illustrated in examples illustrated, such as may be desired for forming a 3D array of devices.

Techniques described herein can provide structures that can be manufactured using methods discussed herein for fabricating 3D microelectronic devices, which can include stand-alone devices or vertical transistors, including 3D sequential circuit builds. Techniques described herein can enable 3D design with method of integration of high performance VFETs. For instance, the present solution can include a fabrication method in which a metal gate electrode of a transistor is formed early in the process as a support or a pillar to hold or carry multiple adjacent materials that can be applied thereon while forming the transistor. In some implementations, as few as only three lithographic masks can be utilized to create an entire array of VFET structures using the gate electrode support structure to provide various instances of self-aligned directional etching.

The present solution can allow for designing the spacing between neighboring transistor devices to reach a scaling limit that can exceed the lithographic printing resolution due to the metal gate first core approach. The present solution can include one or more process flows or techniques for fabricating semiconductor circuits, as can be shown with high performance materials that may not utilize epitaxial growth. The present solution can allow for the fabrication of a stack of N transistors in height and can use utilize conductive oxides along with any semiconductive materials. The present solution can allow for a fabrication of a double node transistor.

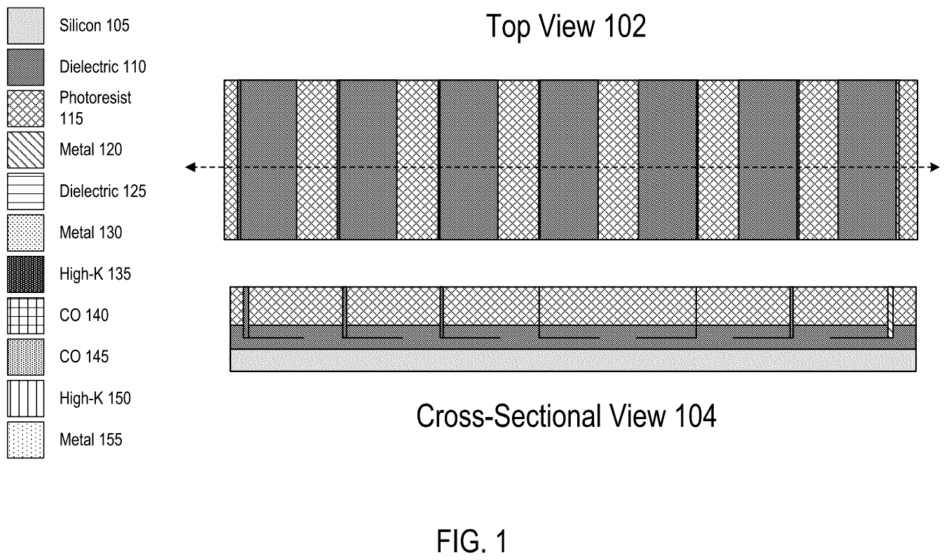

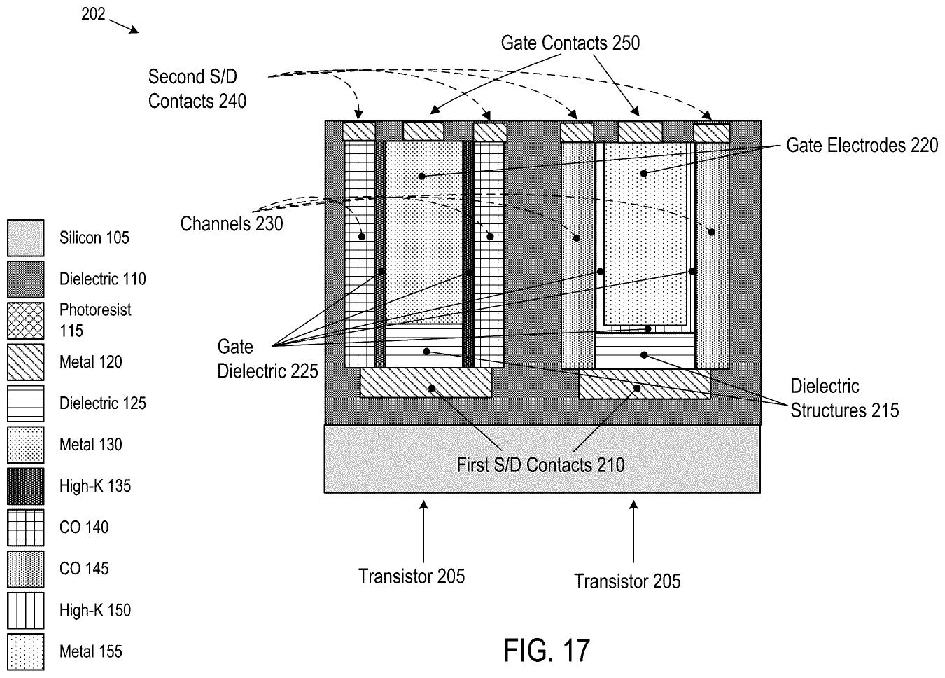

Prior to describing the fabrication steps for manufacturing the present solution, it may be useful to first briefly overview an example of a vertical transistor structure 202 having one or more double-node transistors 205 completed in accordance with the methods of the present solution. Illustrated in FIG. 17 is an example of a cross-sectional view of a portion of vertical transistor structure 202 formed using the steps and techniques discussed in FIGS. 1-16. FIG. 17 shows two 3-D VFET transistors 205 that can be formed on top of a dielectric 105 material that can be deposited on substrate, such as a silicon 105 substrate. Each transistor 205 can include a first source/drain (S/D) contact 210 implemented using metal 120, on top of which can be formed a dielectric structure 215 having a dielectric 125 material. Extending vertically above the dielectric structure 215 can be a gate electrode 220, which can be implemented using metal 130. The gate electrode 220 can serve as a structural support for other parts of the transistor 205 that can be applied or formed thereon.

A gate dielectric 225 can be formed using a thin film of high-k dielectric material, such as high-k 135 or a high-k 150, by being deposited on the sidewalls of the gate electrode 220. In the illustrated example, a first part of the gate dielectric 225 is formed on the outer surface of a first one of the two sidewalls of the gate electrode 220, while a second part of the gate dielectric 225 is formed on the second sidewall of the gate electrode 220. Also supported by the gate electrode 220 is a channel 230 of the transistor 205, which can be formed using conductive oxide materials, such as conductive oxide 140 (referenced to in the Figures as “CO 140”) or conductive oxide 145 (referenced to in the Figures as “CO 145”), which can be deposited on top of the gate electrode 220. Additionally or alternatively, the channel 230 can be formed using one or more 2D materials. A first part of a channel 230 can be formed vertically along the outer surface of the gate dielectric 225 layer by depositing a conductive oxide material (and/or a 2D material) on top of the gate dielectric 225 formed on the first sidewall of the gate electrode 220, while the second part of the channel 230 can be formed vertically along the outer surface of the gate dielectric 225 by depositing a conductive oxide material (and/or 2D material) on top of the gate dielectric 225 formed on the second sidewall of the gate electrode 220. On top of the two parts of the channel 230 in each transistor 205 can be two parts of the second S/D contact 240. The first part of the second S/D contact 240 can be formed with metal 120 on top of the first part of the channel 230, while the second part of the second S/D contact 240 can be formed using the same or a different metal 120 on top of the second part of the channel 230. A gate contact 250 can be formed on top of the gate electrodes 220 of the transistors 205 using metal 120, thus completing the source, drain and gate contacts of the transistors 205 in the transistor structure 202.

FIGS. 1-18 provide a series of illustrations related to an embodiment of a fabrication flow for manufacturing double-node VFET transistors 205. Transistors 205 can be organized in a densely packed array of rows and columns of a transistor structure 202 and can include designs that can vary in alternating fashion, such that for example even-numbered transistors in a row are of a first design and odd-numbered transistors in the row are of a second design. The designs can vary in the type of material that is used for making different parts of the transistor 205, such as channels 230 or gate dielectrics 225. The designs of transistors 205 can also vary based on the way gate dielectrics 225 are designed. For example, some transistors 205 can have a gate dielectric 225 having only two parts, each part extending along either of the two sidewalls of gate electrodes 220 and dielectric structures 215, without any gate dielectric 225 between the gate electrode 220 and the dielectric structures 215. Some transistors 205 can have gate dielectrics 225 having three parts, such that two extend along either of the two sidewalls of gate electrodes 220 and a third one extending between the gate electrode 220 and the dielectric structure 215, while no gate dielectric 225 extends along the sidewalls of the dielectric structure 215. The present disclosure can provide an array of such transistors, where transistors fabricated using the techniques provided herein vary between each other based on these designs and in an alternating fashion.

As described in greater detail in FIGS. 1-18, the illustrated transistor structure 202 can be fabricated using only three photolithographic masks, leveraging a simple, streamlined and efficient 3D VFET fabrication methodology and relying on the gate electrodes 220 for various aspects of the fabrication, including self-aligned directional etching. For example, using the fabrication techniques of the present disclosure, a transistor structure 202 having an array of a plurality of rows and columns of double-node VFET transistors 205 can be built utilizing gate electrodes 220 of every other alternating transistor 205 of the array, as support structures during the fabrication process. Once completed, transistors 205 can be natural “on” state transistors.

Referring now to FIG. 1, a cross-sectional view 104 and a top view 102 are illustrated in the cross-sectional view 104 represents a cross-section taken along the double sided arrow shown horizontally traversing the top view 102. In FIG. 1, a layer of dielectric 110 material is deposited on a substrate, which in the illustrated example is a silicon 105 substrate. Using a mask, such as a bottom metal contact mask, dielectric 110 can be directionally etched while keeping insulation with the silicon 105 substrate. For example, as shown in the cross-sectional view 104, the resulting structure at this fabrication stage can include a layer of photoresist 115 on top of the dielectric 110, where channels can be etched through the photoresist 115 and into the dielectric 110 layer, while maintaining the depth of the etch above the silicon 105, thus clearing the silicon 105 substrate.

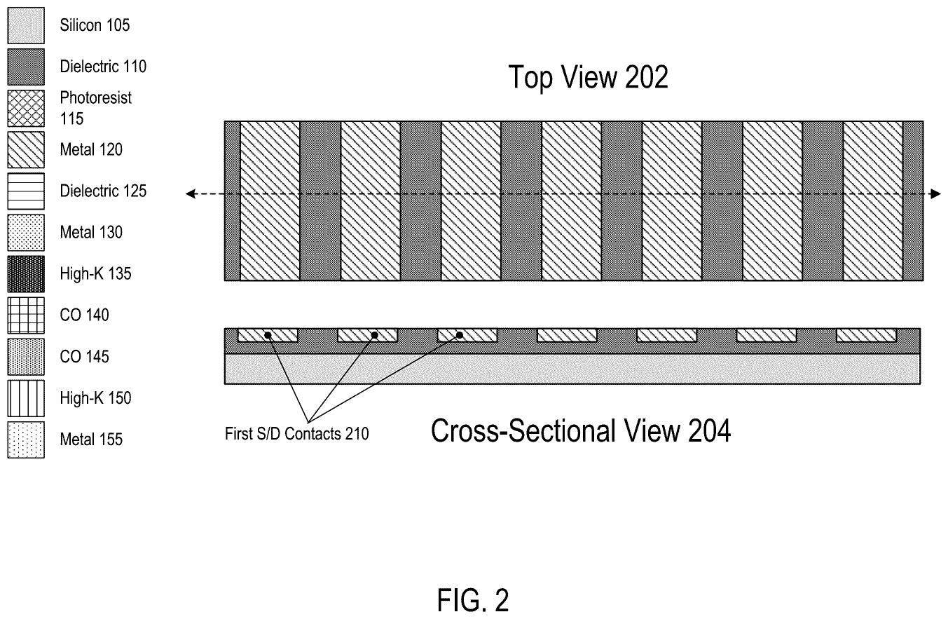

Referring now to FIG. 2, a cross-sectional view 204 and a top view 202 are illustrated in which the cross-sectional view 204 represents a cross-section taken along the double-sided arrow shown horizontally traversing the top view 202. As shown in FIG. 2, metal 120 can fill in the etched out tranches, which can be followed by a chemical and mechanical polishing (CMP). For instance, after stripping off the photoresist 115, metal 120 can be filled into the etched out trenches, followed by a CMP. The resulting metal 120 structure can form first S/D contacts 210 of the transistors 205 in the transistor structure 202.

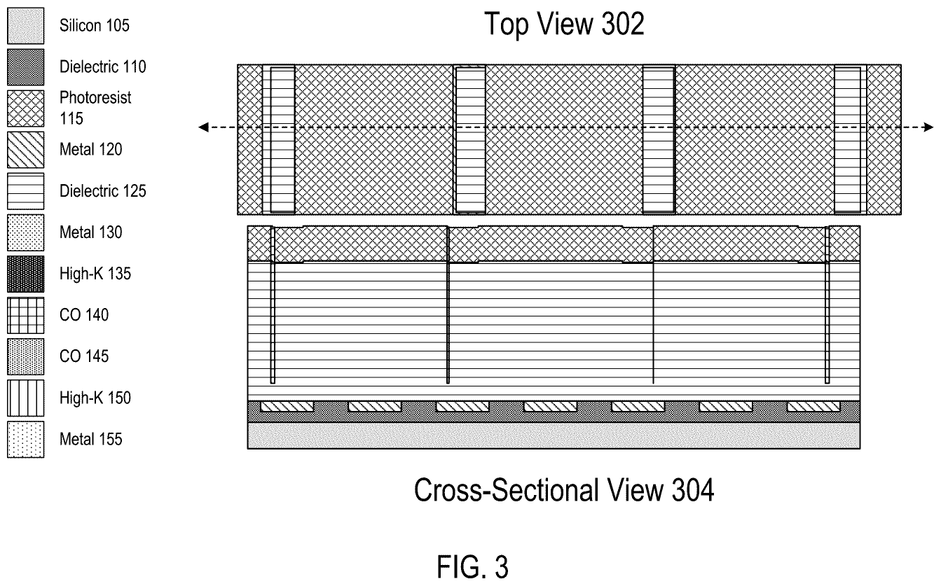

Referring now to FIG. 3, a cross-sectional view 304 and a top view 302 are illustrated in which the cross-sectional view 304 represents a cross-section taken along the double-sided arrow shown horizontally traversing the top view 302. A layer of dielectric 125 can be deposited on top of the structure completed in FIG. 2. The layer of dielectric 125 can have a thickness that is greater than the thickness of the metal trench filled with metal 120 in FIG. 2. For example, dielectric layer 125 can have a thickness that is multiple times greater than the thickness of the filled metal trench. Using a VFET mask, dielectric 125 can be directionally etched, such that the etch stops at the top of the dielectric 110 layer. The etch can also stop at the top of the metal 120 layer. The etch can also stop at a set thickness above the top surface of dielectric 110 layer. As seen in FIG. 3, the etch can be performed over every other first S/D contact 210 of the transistor structure 202, thus skipping half of the first S/D contacts 210 and etching on top of other half first S/D contacts 210.

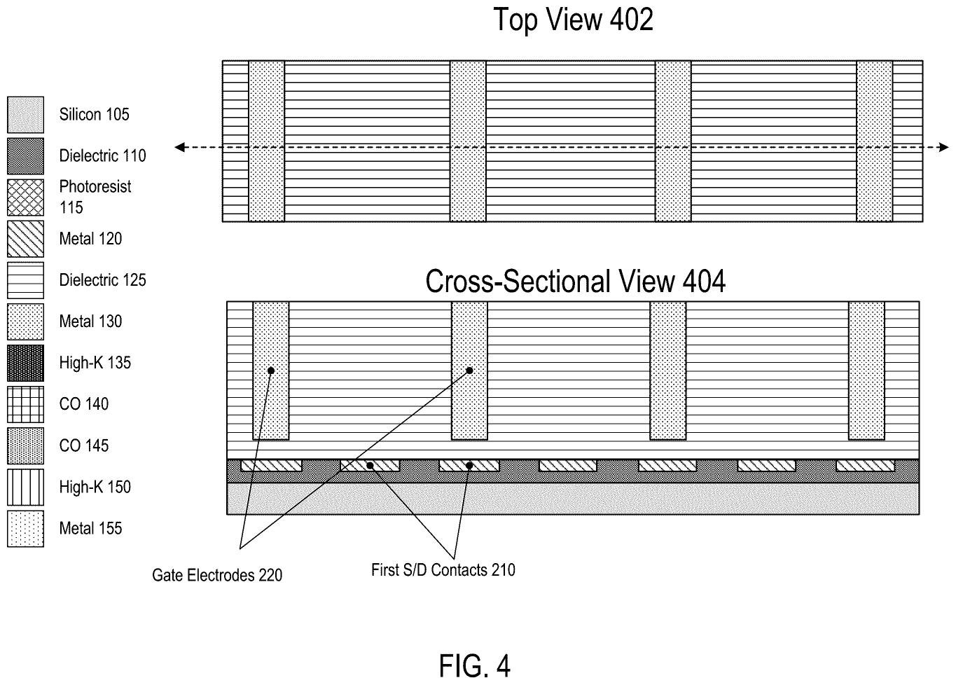

Referring now to FIG. 4, a cross-sectional view 404 and a top view 402 are illustrated in which the cross-sectional view 404 represents a cross-section taken along the double-sided arrow shown horizontally traversing the top view 402. Metal 130 can be deposit filled into the etched out portion (e.g., trench) left by etching completed at FIG. 3. After metal 130 is deposit filled into the etched out trench, a CMP can be performed to remove the surplus material. The remaining metal 130 structure will form a gate electrode 220. As shown in FIG. 4, the gate electrode 220 can be separated from the first S/D contacts 210 by a portion of intervening dielectric 125.

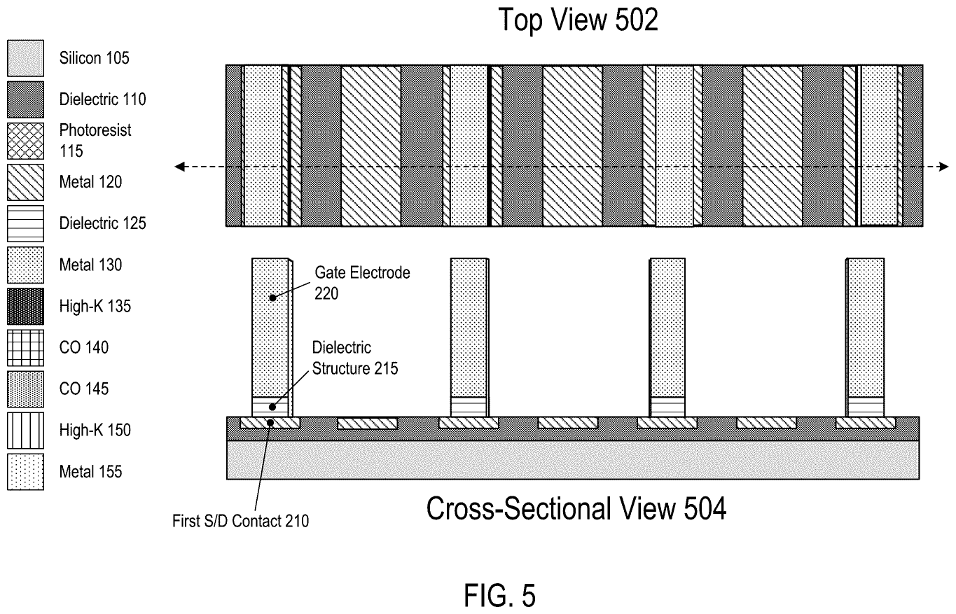

Referring now to FIG. 5, a cross-sectional view 504 and a top view 502 are illustrated in which the cross-sectional view 504 represents a cross-section taken along the double-sided arrow shown horizontally traversing the top view 502. In FIG. 5, dielectric 125 can be etch removed directionally, so that dielectric 125 can be removed everywhere except underneath the gate electrodes 220, which can serve as masks protecting the dielectric 125 beneath the gate electrodes 220 from being removed. The remaining portions of dielectric 125 can form dielectric structure 215, providing an isolation between the metal 120 in the dielectric 110 (e.g., first S/D contact 210) and the metal 130 structure (e.g., the gate electrode 220).

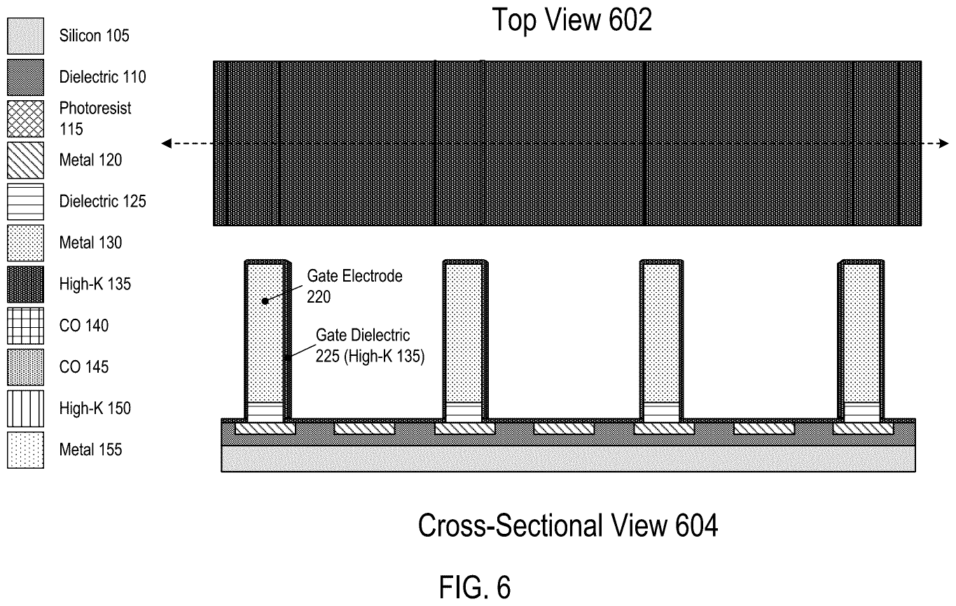

Referring now to FIG. 6, a cross-sectional view 604 and a top view 602 are illustrated in which the cross-sectional view 604 represents a cross-section taken along the double-sided arrow shown horizontally traversing the top view 602. In FIG. 6, high-k 135 material can be deposited on all exposed surfaces of the structure in FIG. 6. For example, high-k 135 deposition can include atomic layer deposition (ALD) that can coat all exposed areas. Upon completion of this step, a thin layer of high-k 135 material can cover all exposed surfaces, as shown in the top view 602, including the outer surfaces (e.g., sidewalls) of the gate electrodes 220.

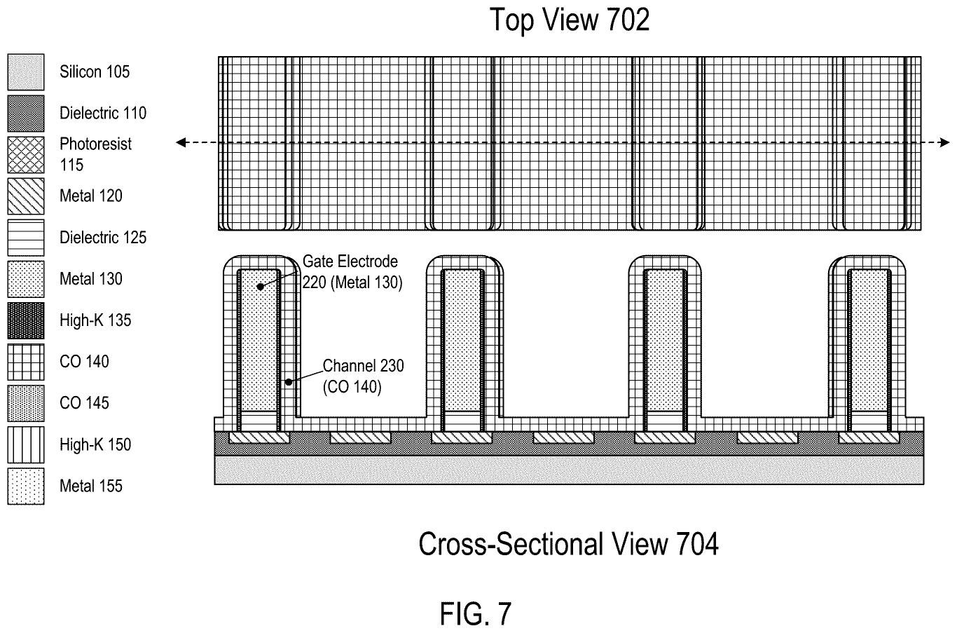

Referring now to FIG. 7, a cross-sectional view 704 and a top view 702 are illustrated in which the cross-sectional view 704 represents a cross-section taken along the double-sided arrow shown horizontally traversing the top view 702. In FIG. 7, high-k 135 can be directionally etched, so that high-k 135 material on horizontal surfaces is removed, which can leave high-k material 135 on the vertical surfaces, including for example the sidewalls of the gate electrodes 220. Upon completion of the directional high-k etching, a conductive oxide 140 can be deposited via, for example, ALD. As a result, a layer of conductive oxide 140 can coat or cover all exposed surfaces, including the surfaces on which high-k 135 material was deposited on the sidewalls of the gate electrodes 220. Conductive oxide 140 can then form the channel 230 on top of the gate dielectric 225.

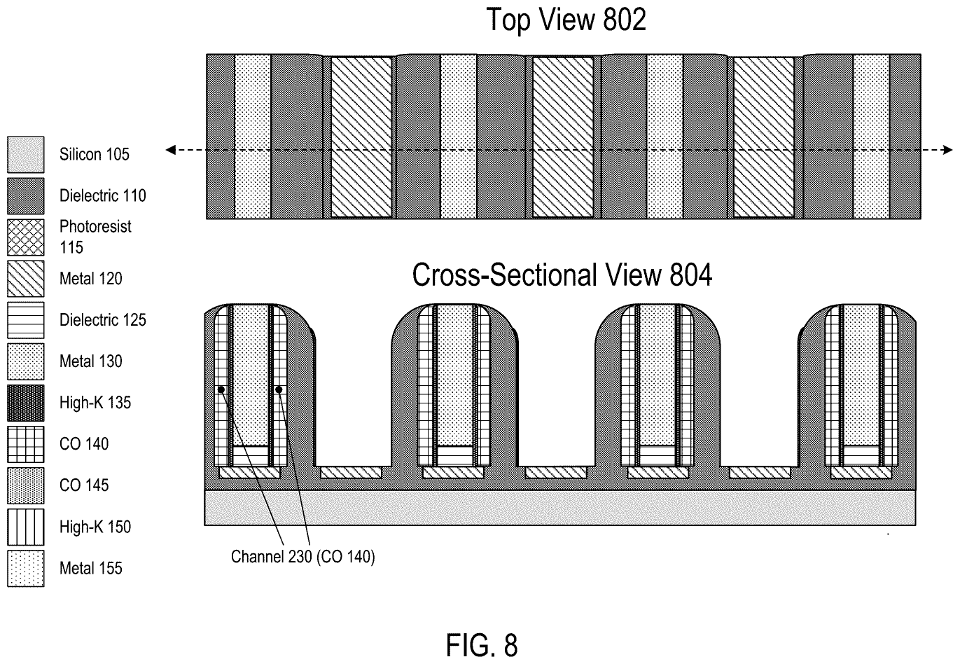

Referring now to FIG. 8, a cross-sectional view 804 and a top view 802 are illustrated in which the cross-sectional view 804 represents a cross-section taken along the double-sided arrow shown horizontally traversing the top view 802. In FIG. 8, conductive oxide 140 is directionally etched so that conductive oxide 140 is removed from the horizontal surfaces, while remaining on the vertical surfaces (e.g., sidewalls of the gate electrodes 220. Then, dielectric 110 can be ALD deposited, followed by a directional etch of the deposited dielectric 110 so that dielectric 110 is removed from the horizontal surfaces. Conductive oxide 140 can, however, remain on the vertical surfaces as the directional etch can remove the material only from the horizontal surfaces (e.g., directionally downward). As a result, two parts of the channel 230 (e.g., deposited conductive oxide 140) on each gate electrode 220 can remain enclosed or sealed within dielectric 110.

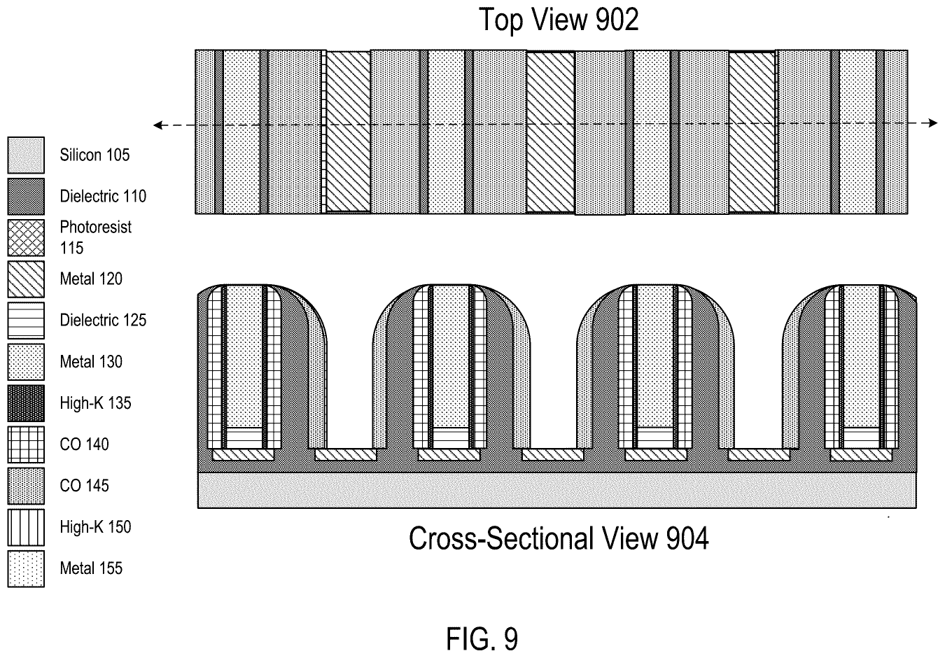

Referring now to FIG. 9, a cross-sectional view 904 and a top view 902 are illustrated in which the cross-sectional view 904 represents a cross-section taken along the double-sided arrow shown horizontally traversing the top view 902. In FIG. 9, ALD deposition of conductive oxide 145 can be implemented. After conductive oxide 145 deposition, conductive oxide 145 can be directionally etched, thus removing the conductive oxide 145 from horizontal surfaces, thus leaving conductive oxide 145 on vertical surfaces supported by gate electrodes 220. As a result, the first S/D contacts 210 of the alternating transistor 205 on top of which gate electrodes 220 are not yet built (e.g., every other alternating first S/D contact 210 that was skipped in FIG. 3) can remain exposed within a trench-like opening as shown in the cross-sectional view 904.

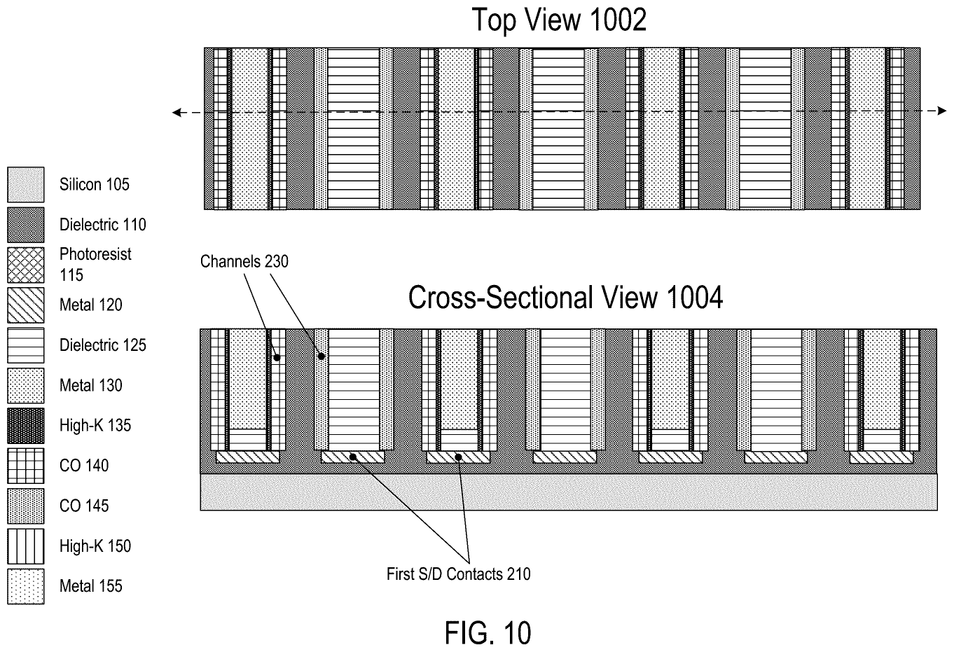

Referring now to FIG. 10, a cross-sectional view 1004 and a top view 1002 are illustrated in which the cross-sectional view 1004 represents a cross-section taken along the double-sided arrow shown horizontally traversing the top view 1002. In FIG. 10, dielectric 125 can be deposit filled into the opening left remaining in FIG. 9 by dielectric 125, after which a CMP can be performed to remove surplus material. The resulting structure can include all first S/D contacts 210 for all transistors 205 with completed channels 230 formed by conductive oxide 140 and/or conductive oxide 145 in alternating fashion, such that every other transistor 205 includes the channel 230 of the same conductive oxide material. In some designs, all transistors 205 can include the same conductive oxide material (e.g., transistors 205 can be all N-type or P-type). In some designs, conductive oxide materials can alternate between transistors 205 (and alternate in N-type and P-type). In some designs, conductive oxide materials can be selected for each individual transistor 205, based on a general design of the transistors structure 202. The CMP can then be performed so as to remove all material down to the surface shown for example in cross-sectional view 1004 so that all channels 230 of all transistors 205 have the same height and have flattened top surfaces.

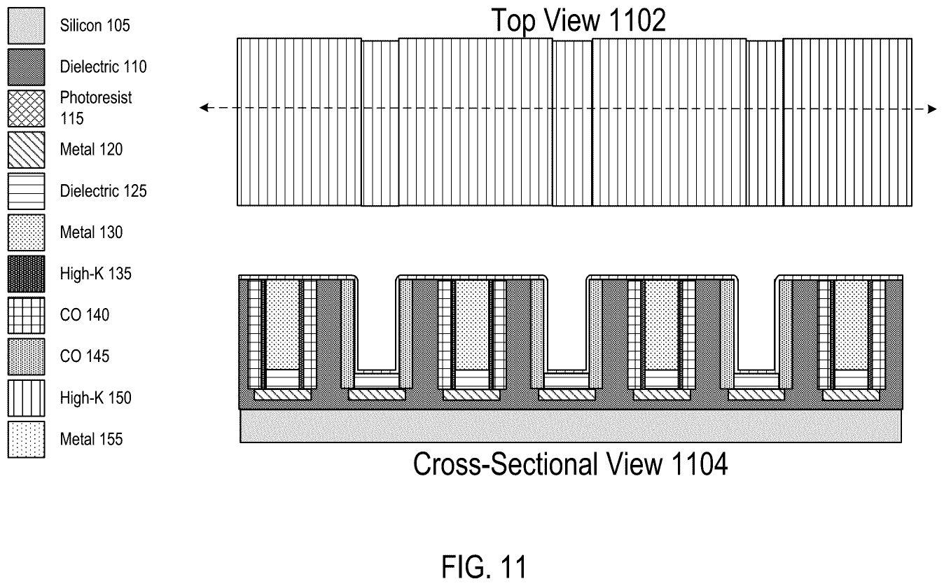

Referring now to FIG. 11, a cross-sectional view 1100 and a top view 1102 are illustrated in which the cross-sectional view 1100 represents a cross-section taken along the double-sided arrow shown horizontally traversing the top view 1102. In FIG. 11, dielectric 125 can be etched out down to a depth that is above the first S/D contact 210, so as to keep a layer of electrical insulation between the metal gate electrode 220 to be fabricated and the first S/D contact 210 beneath. A layer of high-k 150 material can be deposited to form a thin film of gate dielectric 225 for the transistors 205 still to be completed (e.g., every other structure for which the gate electrode 220 is yet to be completed).

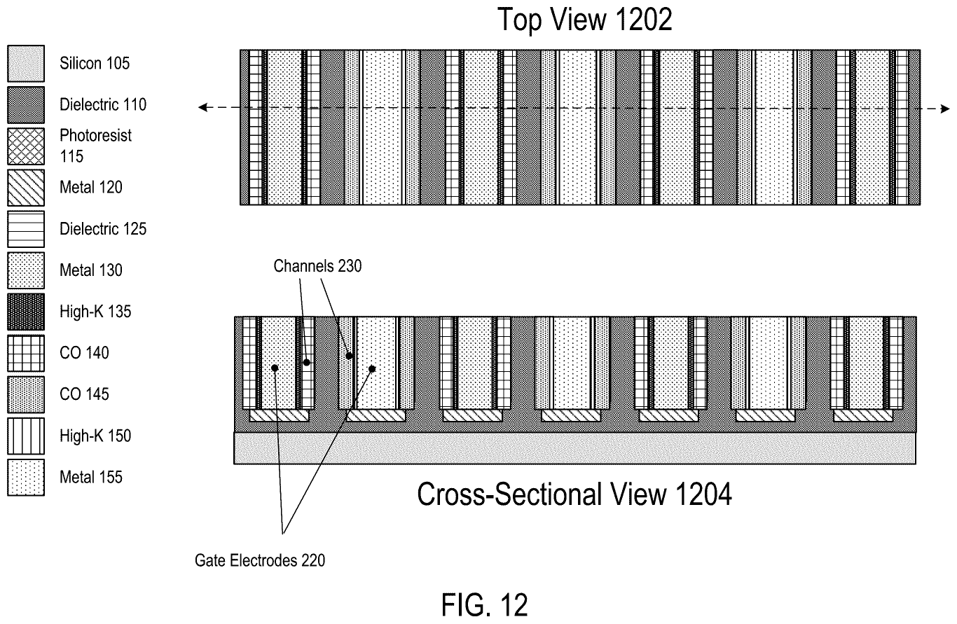

Referring now to FIG. 12, a cross-sectional view 1200 and a top view 1202 are illustrated in which the cross-sectional view 1200 represents a cross-section taken along the double-sided arrow shown horizontally traversing the top view 1202. At FIG. 12, metal 155 can be deposit filled into the etched out trench and on top of the high-k 150 material, so as to fill in the trench, thereby creating the gate electrode 220 for each remaining alternating transistor 205. In doing so, the completed gate electrode 220 will then interface with a gate dielectric 225 and its conductive oxide channel 230 on its outer walls. Following this, a CMP can be performed to remove surplus materials.

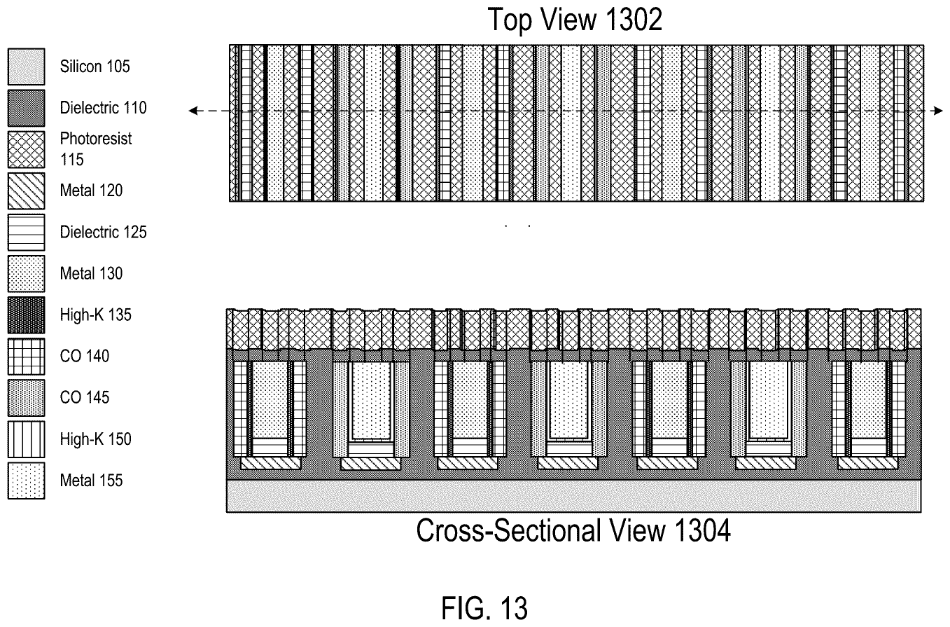

Referring now to FIG. 13, a cross-sectional view 1304 and a top view 1302 are illustrated in which the cross-sectional view 1304 represents a cross-section taken along the double-sided arrow shown horizontally traversing the top view 1302. In FIG. 13, a layer of dielectric 110 is deposited on top of the exposed top surface of the structure. Using a top metal contact mask and a layer of photoresist 115, a dielectric 110 can be directionally etched down to the material other than dielectric 110. This means that directional downward etch will stop when the etch encounters the features of the transistors 205, other than dielectric 110.

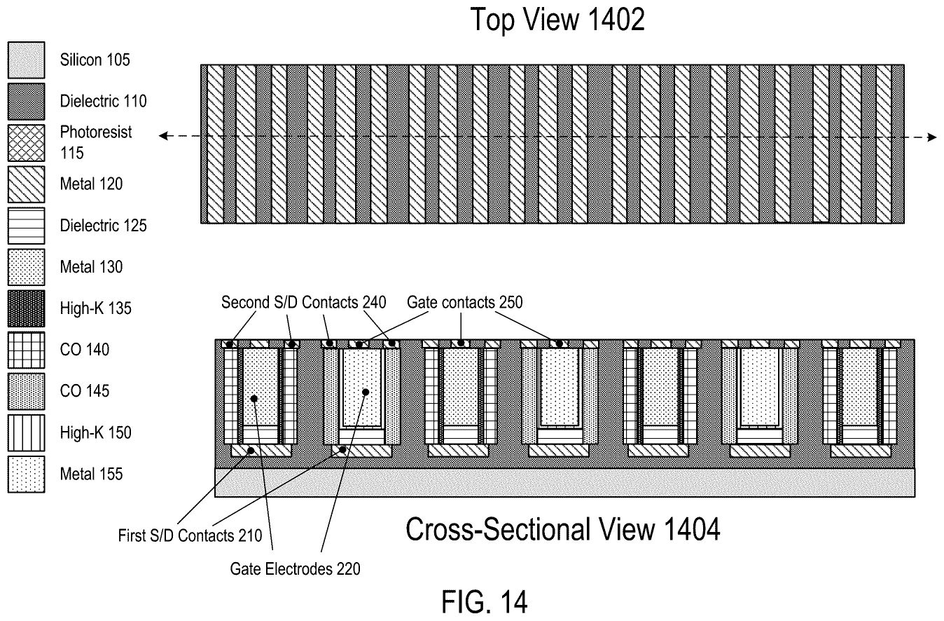

Referring now to FIG. 14, a cross-sectional view 1404 and a top view 1402 are illustrated in which the cross-sectional view 1404 represents a cross-section taken along the double-sided arrow shown horizontally traversing the top view 1402. In FIG. 14, after stripping the photoresist 115, the etched out areas can be deposit filled with metal 120, after which a CMP can be performed to remove surplus material. As a result, second S/D contacts 240 and gate contacts 250 can be formed, as shown in cross-sectional view 1404.

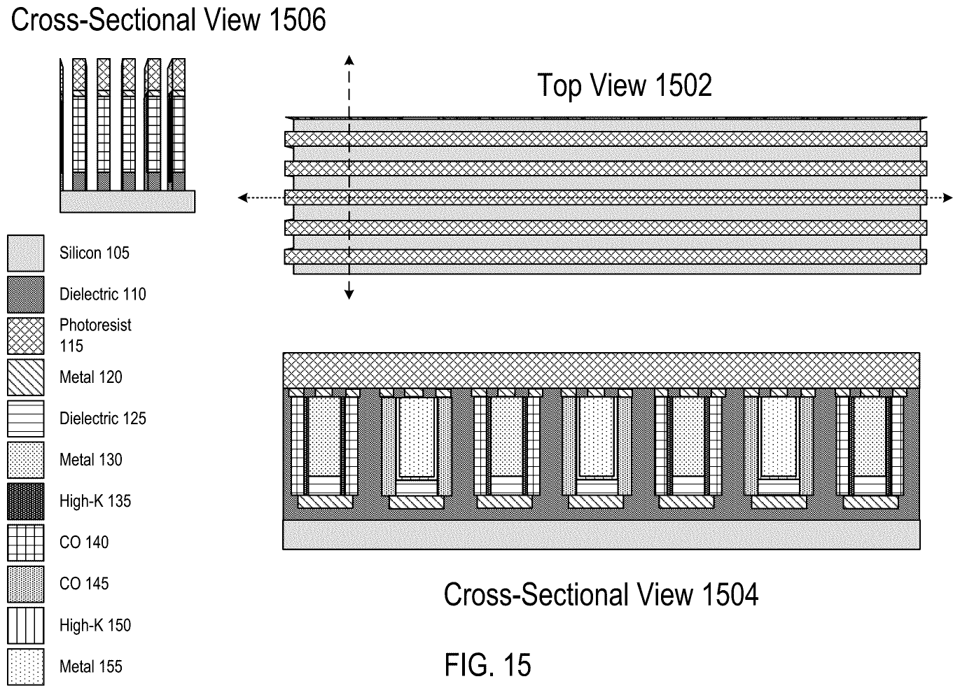

Referring now to FIG. 15, a cross-sectional views 1504 and 1506 and a top view 1502 are illustrated in which the cross-sectional view 1504 represents a cross-section taken along the double-sided arrow shown horizontally traversing the top view 1502 and cross-sectional view 1506 represents a cross-section taken along the double sided arrow vertically traversing the top view 1502. In FIG. 15, a layer of photoresist 115 can be applied upon which a slicing mask can be used to etch directionally (e.g., along the direction of the double-sided horizontal arrow) trenches to separate transistors 205 into multiple rows of transistors. The etching can be performed along the entire depth of the structure down to silicon 105 material. In some implementations, the etch can be performed down to a layer of dielectric 110 above the silicon 105. The resulting transistor structure 202 can include an array of multiple rows and columns of transistors 205, which can then be insulated subsequently with a dielectric material.

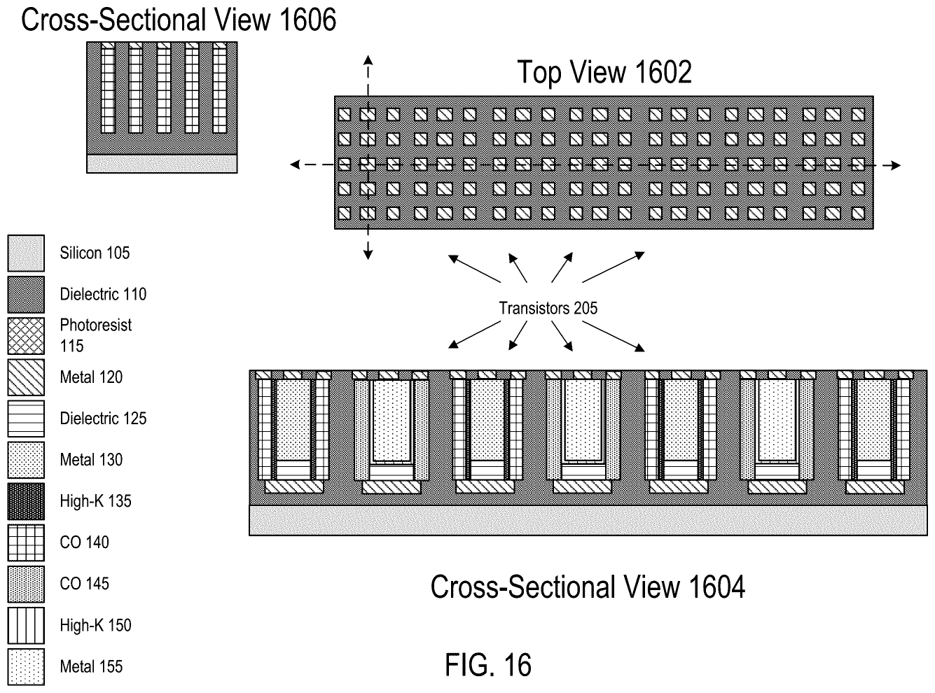

Referring now to FIG. 16, a cross-sectional views 1604 and 1606 and a top view 1602 are illustrated in which the cross-sectional view 1604 represents a cross-section taken along the double-sided arrow shown horizontally traversing the top view 1602 and a cross-sectional view 1606 represents a cross-section taken along the double sided arrow vertically traversing the top view 1602. In FIG. 16, after stripping the photoresist 115, dielectric 110 can be deposit filled into the trenches etched out in FIG. 15, followed by CMP. Dielectric 110 can electrically isolate each transistor 205, completing the fabrication of the transistor structure 202 in accordance with this embodiment.

Referring back to FIG. 17, a completed zoom-in view of the two of the transistors 205 of the transistor structure 202 is illustrated showing each of the features of each of the transistors 205, which as described earlier, includes first S/D contacts 210 on top of which are dielectric structures 215 and gate electrodes 220. During the manufacturing process, the gate electrodes 220 for every other transistor 205 (along the width of the cross-sectional views of the figures) is constructed so as provide a structural support for gate dielectrics 225 and channels 230 that are supported on their sidewall surfaces. Leveraging the gate electrodes 220 as shown in FIGS. 1-12, the every other (remaining) gate electrode 225 can be built by filling in the metal 155 into the remaining openings on top of first S/D structures 210 not yet completed. Then, once each gate electrode 220 of each transistor 205 is complete, the second S/D contacts 240 and gate contacts 250 are formed, thereby completing all transistors 205 in the transistor structure 202. As shown in the example process discussed in connection with FIGS. 1-16, the entire process can involve only three masks, while other directional etching and processing can be done using features of the structure itself. It should be understood that alternative number of masks may be utilized, but the use of three masks minimizes processing.

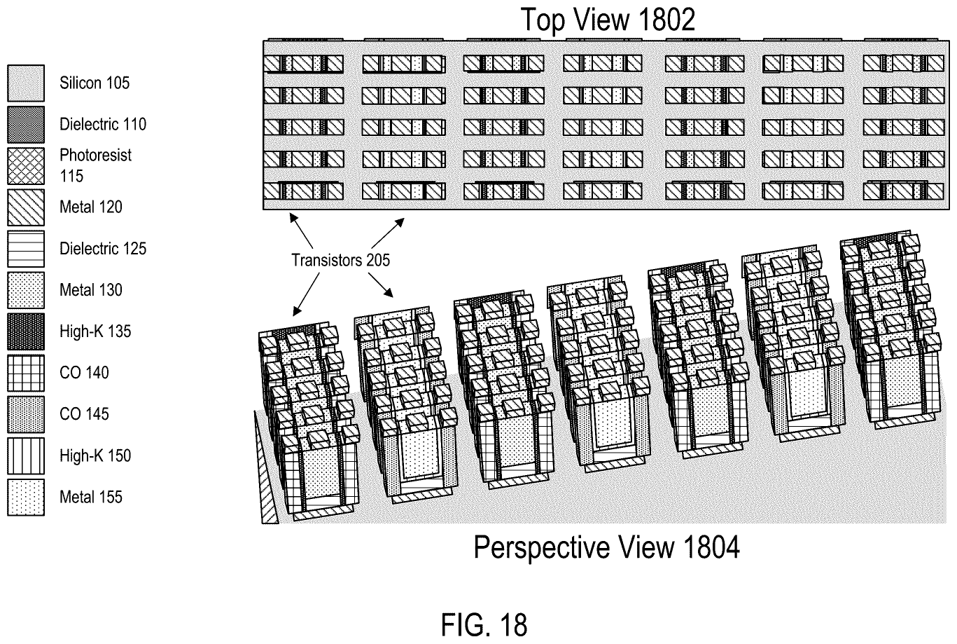

Referring now to FIG. 18, including a perspective view 1804 and a top view 1802, a completed transistor structure 202 can include an array of rows and columns of transistors 205. As shown in perspective view 1804, a transistor structure 202 can include many rows and many columns of transistors 205. Because transistors 205 are fabricated as VFETs, they can be spaced very densely, thus improving the number of devices per surface area. The transistors in FIG. 18 are double-node transistors, which can mean that their pull strength is doubled due to two nodes (e.g., parts) that can be used for activating the channel 230.

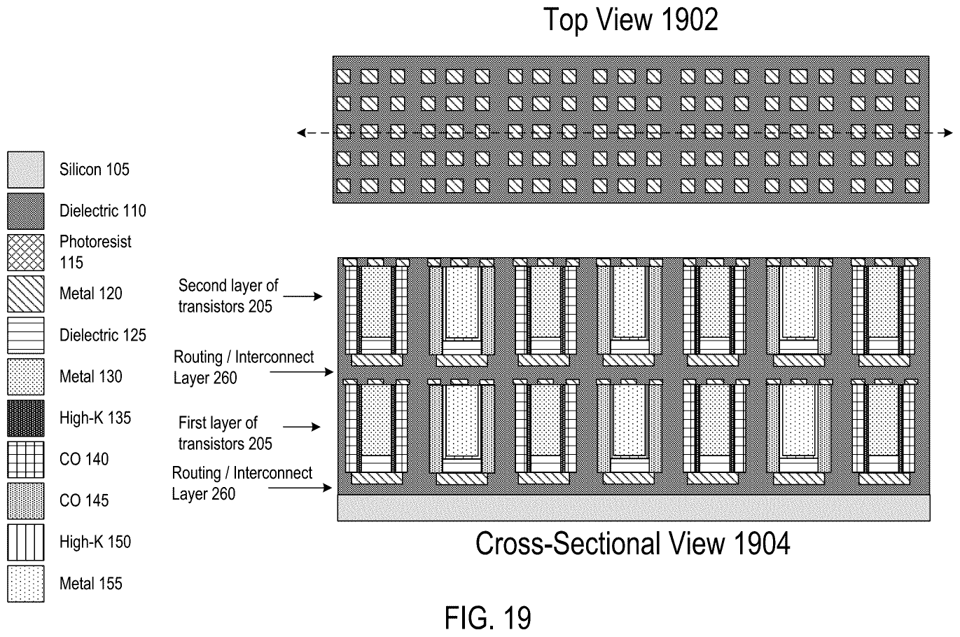

Referring now to FIG. 19, a cross-sectional view 1904 and a top view 1902 are illustrated in which the cross-sectional view 1902 represents a cross-section taken along the double-sided arrow shown horizontally traversing the top view 1902. FIG. 19 illustrates stacking of transistors 205 one on top of another. For example, cross-sectional view 1904 shows a second layer of transistors 205 stacked on top of a first layer of transistors 205 that are formed on a layer of dielectric on a substrate 105. Below the first layer of transistors 205 as well as between the two layers of transistors 205 can be a routing/interconnect layer 260. A routing/interconnect layer 260 can include a dielectric material, such as dielectric 110, in which routing and interconnection of electrical lines and contacts for connecting transistors 205 can be formed. The routing and interconnection lines can include contacts for connecting to transistors 205 in the first layer, the second layer and both the first and the second layers. Layers of transistors 205 can include different polarity transistors, such as N-type and P-type, so that N-type and P-type transistors alternate, one on top of another. Transistors 205 can also alternate in terms of their type laterally along the direction of the double sided arrow in the FIG. 19. Routing/interconnect layer 260 can include connections for transistors 205 to form memory, logic or any other circuitry.

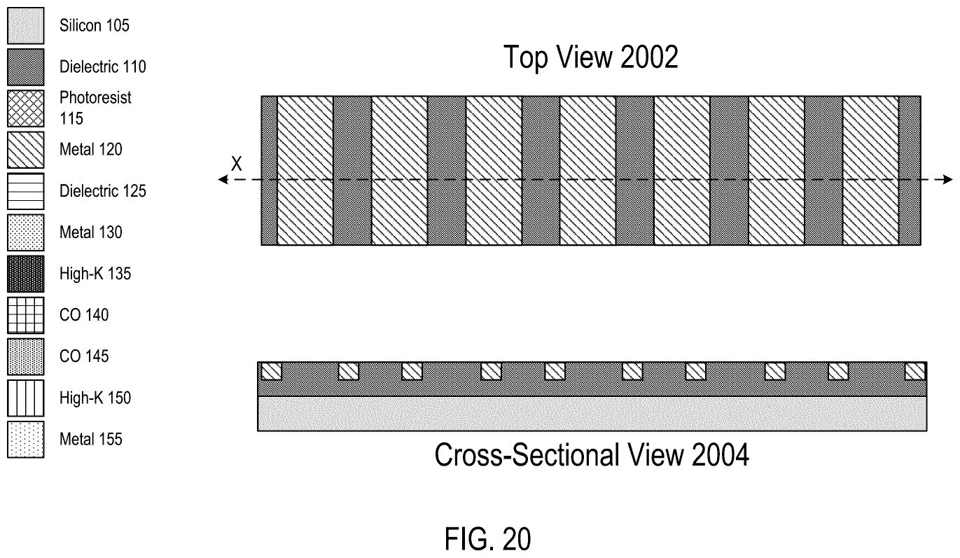

Referring now to FIGS. 20-24, an example embodiment of fabrication steps for fabricating a design of single node transistors 205 is presented. In FIGS. 20-24, a densely packed array of single-node transistors 205 can be fabricated utilizing fabrication steps for double-node transistors 205 similar to those discussed in connection with FIGS. 1-16, where the double-node transistors 205 of FIGS. 1-16 can be sliced vertically across the middle to separate them along the gate contacts 250 into two single node transistors 205.

Referring now to FIG. 20, a cross-sectional view 2004 and a top view 2002 are illustrated in which the cross-sectional view 2004 represents a cross-section taken along the double-sided arrow shown horizontally traversing the top view 2002. In FIG. 20 steps same or similar to those completed in connection with FIGS. 1-2 can be implemented. For example, dielectric layer 110 can be deposited on Si 105, after which a layer of photoresist 115 can be applied and a bottom metal mask can be used to directionally etch dielectric 110, while keeping the insulation with substrate 105. After stripping the photoresist 115, deposit fill using metal 120 can be implemented to fill in the etched out material to form first S/D structures 210. The bottom metal mask however can be different from the one in FIGS. 1-2, and so the first S/D structures 210 can be differently shaped, as shown in FIG. 20.

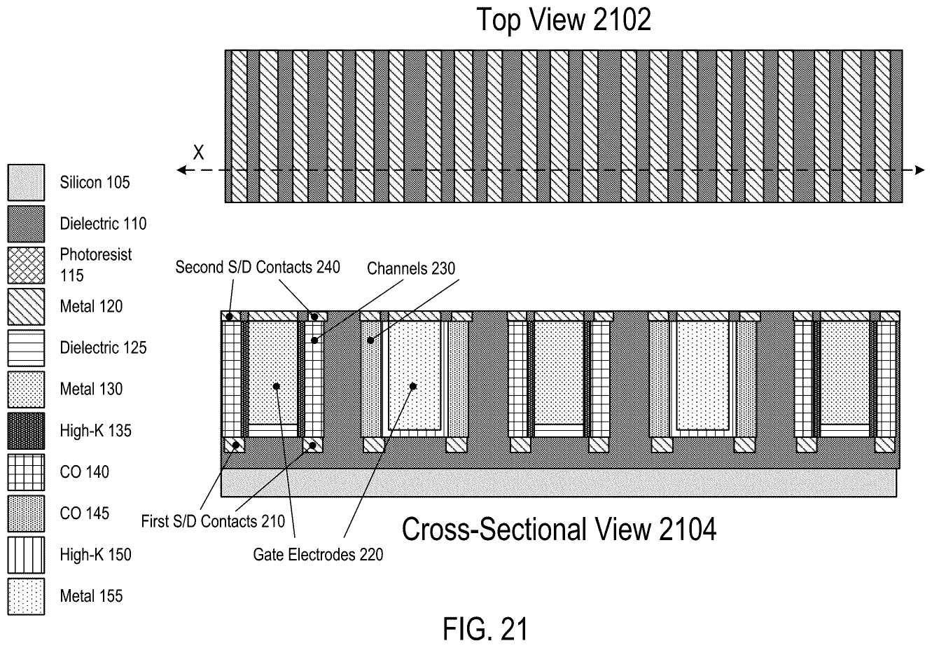

Referring now to FIG. 21, a cross-sectional view 2104 and a top view 2102 are illustrated in which the cross-sectional view 2104 represents a cross-section taken along the double-sided arrow shown horizontally traversing the top view 2102. In FIG. 21, we can see the outcome of the single-node 3D VFET transistor structure 202 after the completion of the steps and fabrication techniques same or similar to those discussed in connection with FIGS. 3-14. The resulting structure includes the same or similar features as the features in FIG. 14, including first S/D structures 210, second S/D structures 240, gate contacts 250, channels 230 and gate electrodes 220. At this stage, the structures have not yet been sliced along the cross-sectional view in order to create an array of transistors 205, as was the case in FIG. 15.

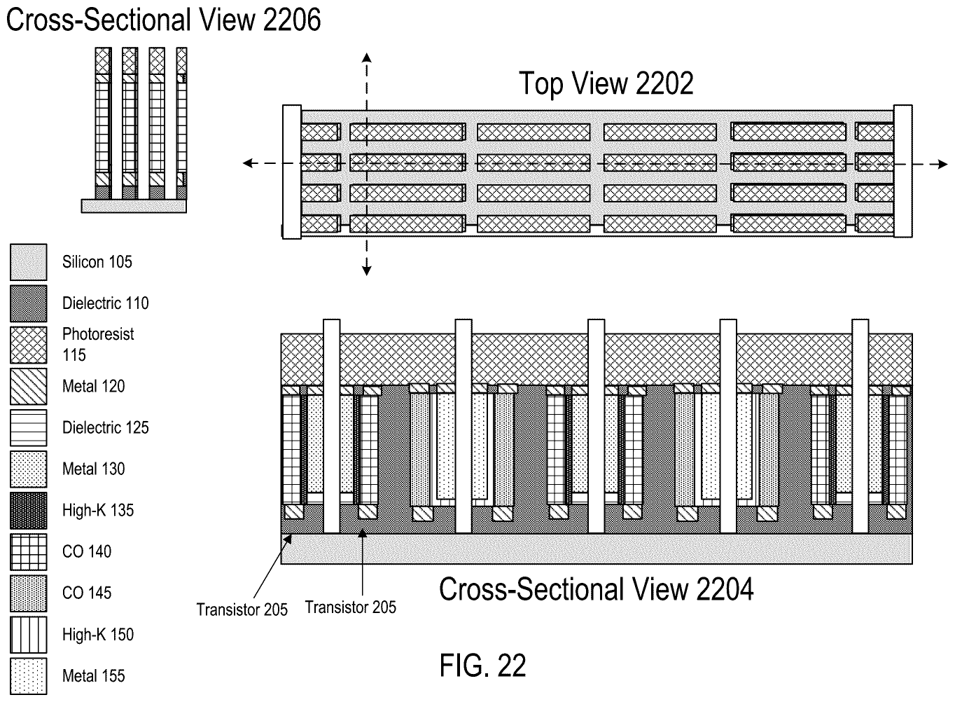

Referring now to FIG. 22, a cross-sectional view 2204, a cross-sectional view 2206 and a top view 2202 are illustrated in which the cross-sectional view 2204 represents a cross-section taken along the double-sided arrow shown horizontally traversing the top view 2202 and the cross-sectional view 2206 represents a cross-section taken along the double-sided arrow shown vertically traversing the top view 2202. In FIG. 22, using a layer of photoresist 115 and a slicing mask a downward etch (e.g., a slice) is performed directionally across the structure, both laterally (along the horizontal double-sided arrow) and longitudinally (along the vertical double-sided arrow) to cut the structure down to the level of silicon 105 into individual parts. As shown in top view 2202, this slicing mask includes slices in both lateral and longitudinal directions, as a result of which one of the cuts is made along the mid-point of each of the structures that formed a double-node transistor 205 in FIG. 15, thus splitting that structure into two single-node transistors 205. As shown in FIG. 22, what used to be a structure from which a double-node transistor 205 in FIGS. 1-16 was created, in FIG. 22 two single node transistors 205 are created.

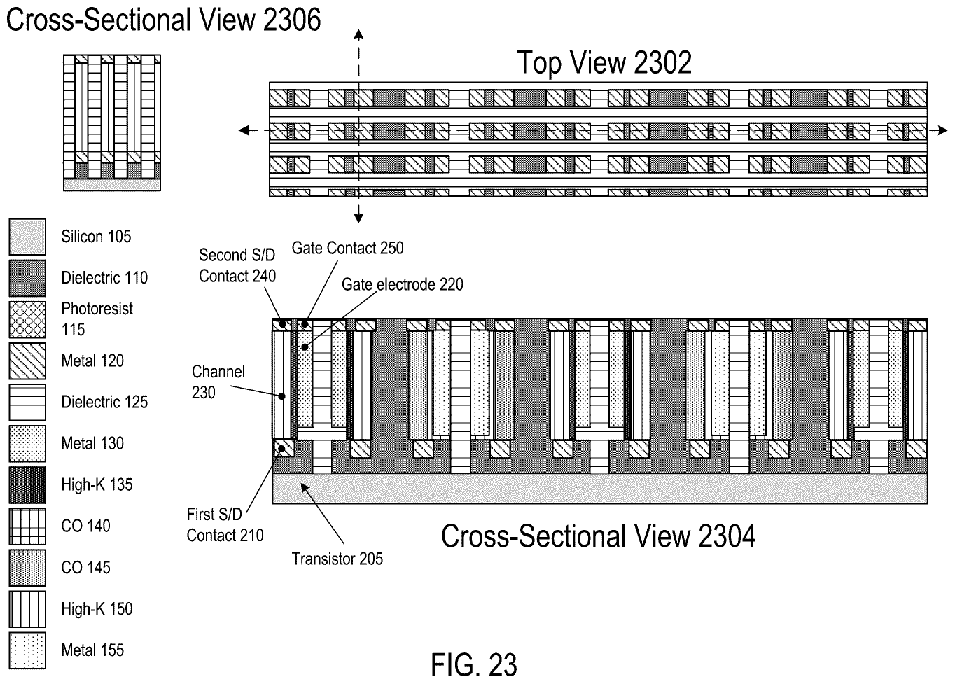

Referring now to FIG. 23, a cross-sectional view 2304, a cross-sectional view 2306 and a top view 2302 are illustrated in which the cross-sectional view 2304 represents a cross-section taken along the double-sided arrow shown horizontally traversing the top view 2302 and the cross-sectional view 2306 represents a cross-section taken along the double-sided arrow shown vertically traversing the top view 2302. In FIG. 22, after stripping off the photoresist 115 from FIG. 22, a deposit fill is completed using dielectric 125 to fill the etched out trenched left by the mask in FIG. 22. Following this step, a CMP is performed to remove surplus material. The resulting structure 202 includes an array of single-node transistors 205, each one of which includes its own first S/D contact 210, gate electrode 220, channel 230 second S/D contact 240 and gate contact 250, as shown in FIG. 23.

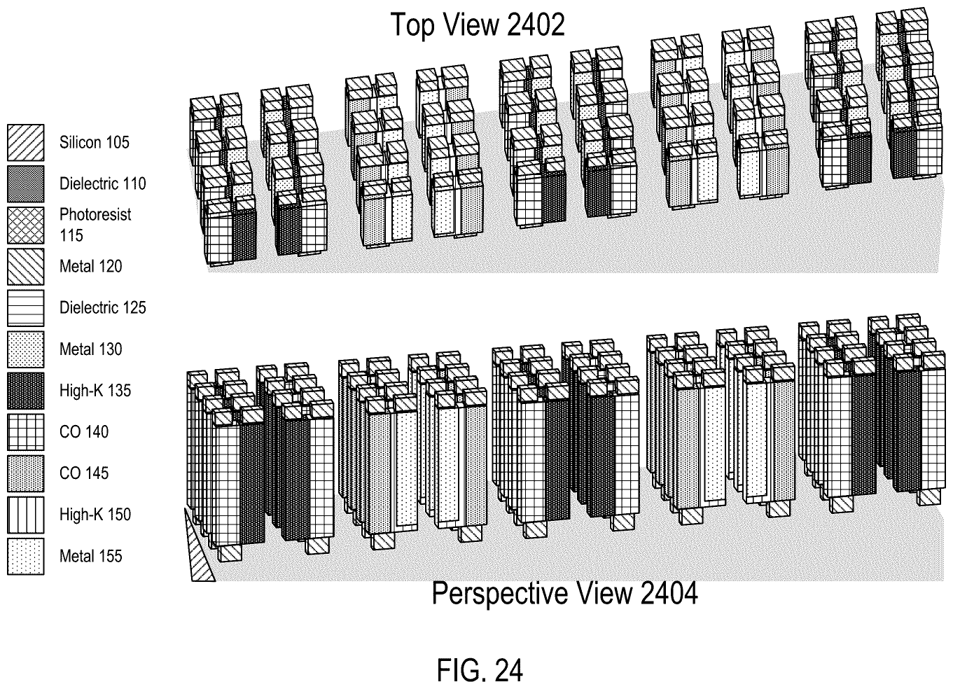

Referring now to FIG. 24, including a perspective view 2404 and a top view 2402, a completed transistor structure 2402 can include an array of rows and columns of single-node transistors 205. As shown in perspective view 2404, a transistor structure 202 can include many rows and many columns of single-node transistors 205. Because single-node transistors 205 are VFETs utilizing slightly more than a half of the structure of double-node transistors 205 of FIGS. 1-16, the transistors 205 can be spaced very densely, thus improving the number of devices per surface area.

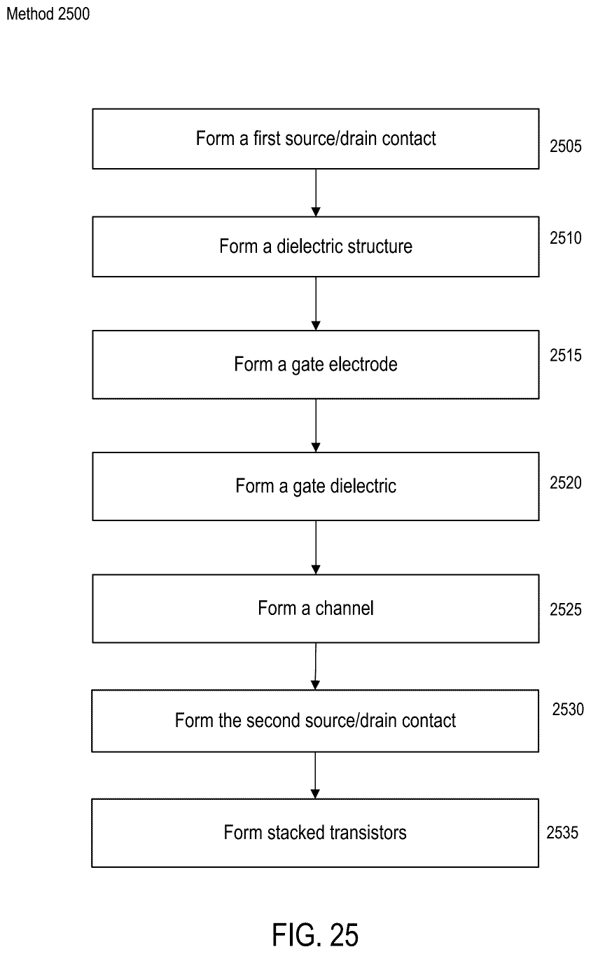

Referring now to FIG. 25, illustrated is a flow diagram of an example method 2500 for fabricating one or more 3D VFET transistors 205 using the fabrication techniques and steps described in FIGS. 1-24. The method 2500 can include steps 2505-2530 which can be used for fabricating single-node or double-node transistors 205. At step 2505, a first source/drain contact is formed. At step 2510, a dielectric structure is formed. At step 2515, a gate electrode is formed. At step 2520, a gate dielectric is formed. At step 2525, a channel is formed. At step 2530, a second source/drain contact is formed. At step 2535, stacked transistors are formed.

At step 2505, a first source/drain contact is formed. The first source/drain contact can be formed using a metal, a doped semiconductor or any other electrically conductive material. The first source/drain contact can be formed for a double node transistor, such as a transistor formed in connection with FIGS. 1-18. The first source/drain contact can be connected to two parts of a channel, each part of the channel formed along the sidewall surface of the gate electrode. The first source/drain contact can be formed for a single-node transistor, such as a transistor formed in connection with FIGS. 20-24. The first source/drain contact can be connected to a channel formed along a single sidewall of a gate dielectric. The first source/drain contact can be formed in a dielectric layer. The dielectric layer can insulate the first source/drain structure from a substrate beneath the first source/drain structure.

At step 2510, a dielectric structure is formed. A dielectric structure can be formed from a dielectric material. The dielectric structure can be formed on top of the source/drain contact. The dielectric structure can be in physical contact with the source/drain contact. The dielectric structure can include an intervening layer or a structure between itself and the source/drain contact. The dielectric structure can be formed using the fabrication steps and techniques discussed in connection with FIGS. 3-5. The dielectric structure can include a rectangular cross-section and can include sidewalls. The sidewalls can vertically align with the sidewalls of the gate electrode to be formed at step 2515.

At step 2515, a gate electrode is formed. The gate electrode can be formed on top of the dielectric structure. The gate electrode can be formed using a metal, a doped semiconductor material or any other electrically conductive material. The gate electrode can be formed using the fabrication steps and techniques discussed in connection with FIGS. 3-5. The gate electrode can include a gate contact in electrical continuity with the gate electrode and located on top of the gate electrode. Gate electrode can include a rectangular cross-section along the width and height. The gate electrode can include a rectangular cross-section along the width and depth. The height of the gate electrode can be greater than its width or its depth. The gate electrode can extend vertically from the dielectric structure. The gate electrode can provide the support for the gate dielectric to be formed at steps 2520 and/or channel to be formed at step 2525. The gate electrode can provide the support for the second source/drain contact to be formed at step 2530. The gate electrode can provide the support for gate contact.

At step 2520, a gate dielectric is formed. A gate dielectric can include a thin film of deposited high-k material. A gate dielectric can be formed using, for example, fabrication steps and techniques discussed in connection with FIGS. 6-7 or FIG. 11. The gate dielectric can include a single part where high-k material is deposited on a single plane. The gate dielectric can include two or more parts, such as where high-k dielectric is formed in two or more planes. A first part of a gate dielectric can be formed vertically along at least a first sidewall of the gate electrode. A second part of a gate dielectric can be formed vertically along at least a second sidewall of the gate electrode. The gate dielectric can be formed by thin film deposition of high-k material, followed by directional downward etch removing gate dielectric from horizontal surfaces and leaving the gate dielectric on the vertical surfaces. Forming the gate electrode includes vertically extending the first part of the gate electrode above the dielectric structure. A height of the gate electrode can be greater than each one of a width and a thickness of the gate electrode. Dimensions of the gate dielectric can be based on the dimensions of the sidewalls of the gate electrode.

Forming the first part of the gate dielectric can include extending the first part of the gate dielectric along a first sidewall of the dielectric structure. The first part of the gate dielectric can be formed in a single plane extending from the first sidewall of the gate electrode to the first sidewall of the dielectric structure. Forming the second part of the gate dielectric further can include extending the second part of the gate dielectric along a second sidewall of the dielectric structure. The second part of the gate dielectric can be formed in a single plane extending from the second sidewall of the gate electrode to the second sidewall of the dielectric structure. Forming a third part of the gate dielectric can be implemented by forming a thin layer of high-k material between a top surface of the dielectric structure and a bottom surface of the gate electrode.

At step 2525, a channel is formed. The channel can be formed by depositing a layer of conductive oxide material. The channel can include a single part channel or multipolar channel. A single-node transistor, such as the one discussed in connection with FIGS. 20-24, can include a single part channel. A double-node transistor, such as the one discussed in connection with FIGS. 1-18 can include multiple parts of a channel. The channel can be formed using any one of, or any combination of, a conductive oxide and a 2D material.

Forming a first part of a channel of the transistor on can be done by depositing a conductive oxide material a surface of the first part of the gate dielectric. Forming a second part of the channel of the transistor can be implemented by depositing a conductive oxide material on a surface of the second part of the gate dielectric. Forming the first part of the channel and the second part of the channel can include forming a respective conductive oxide material (i) abutting the gate dielectric and (ii) extending vertically along the gate electrode.

A channel can be formed using the fabrication techniques and steps discussed in connection with FIGS. 7-10. A dual-node transistor can include a first and a second part of the channel. The first part of the channel can be formed to be in contact with the first source/drain contact. The second part of the channel can be formed to be with the first source/drain contact.

At step 2530, the second source/drain contact is formed. The second source/drain contact can be formed using metal, a doped semiconductor or any other electrically conductive material. Second source/drain contact can be formed on top of the channel. The second source/drain contact can include a single part, such as in single-node transistors, discussed in connection with FIGS. 20-24. The second source/drain contact can include multiple parts, such as in dual-node transistors, discussed in connection with FIGS. 1-18. A first part of a second source/gate structure of the transistor can be formed on top of the first part of the channel. A second part of the second source/gate structure of the transistor can be formed on top of the second part of the channel.

At step 2535, form stacked transistors. For example, a second transistor can be formed on top of a first transistor that can be formed in connection with fabrication steps discussed in connection with FIGS. 1-18. Stacked transistors can include transistors formed, such as those described in connection with FIG. 19. For example, a second transistor can be formed on top of a first transistor. The second transistor can include a first source/drain contact of a second transistor above the first and second parts of the second source/drain contact. A dielectric structure of the second transistor can be formed on top of the first source/drain contact of the second transistor. A gate electrode of the second transistor can be formed on top of the dielectric structure of the second transistor. A first part of a gate dielectric of the second transistor can be formed along at least a first sidewall of the gate electrode of the second transistor. A second part of the gate dielectric of the second transistor can be formed along at least a second sidewall of the gate electrode of the second transistor. A first part of a channel of the second transistor can be formed on a surface of the first part of the gate dielectric of the second transistor. A second part of the channel of the second transistor can be formed on a surface of the second part of the gate dielectric of the second transistor. A first part of the second source/gate contact of the second transistor can be formed on top of the first part of the channel of the second transistor. A second part of the second source/gate contact of the second transistor can be formed on top of the second part of the channel of the second transistor. A routing layer comprising one or more metal connections for routing electrical signals to one or more of the transistor or the second transistor can be formed above the first and the second parts of the second source/drain contact and below the second transistor,

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features described only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A semiconductor transistor structure, comprising:
a first source/drain contact of a transistor;
a dielectric structure formed on top of the first source/drain contact;
a gate electrode of the transistor formed on top of the dielectric structure;
a gate dielectric comprising a first part formed vertically along at least a first sidewall of the gate electrode and a second part formed vertically along at least a second sidewall of the gate electrode;
a channel of the transistor comprising a first part formed on a surface of the first part of the gate dielectric and a second part formed on a surface of the second part of the gate dielectric; and
a second source/drain contact of the transistor comprising a first part on top of the first part of the channel and a second part on top of the second part of the channel.

2. The semiconductor transistor structure of claim 1, wherein the gate electrode extends vertically above the dielectric structure, a height of the gate electrode being greater than each a width and a thickness of the gate electrode.

3. The semiconductor transistor structure of claim 1, wherein the first part of the channel and the second part of the channel each comprise a conductive oxide material (i) abutting the gate dielectric and (ii) extending vertically along the gate electrode.

4. The semiconductor transistor structure of claim 1, wherein the first part of the gate dielectric further extends along a first sidewall of the dielectric structure, and wherein the second part of the gate dielectric further extends along a second sidewall of the dielectric structure.

5. The semiconductor transistor structure of claim 1, wherein a gate contact is formed on top of the gate electrode and at a same height as the first and second parts of the second source/drain contacts.

6. The semiconductor transistor structure of claim 1, wherein a dielectric material layer insulates the first source/drain contact from a substrate beneath the first source/drain contact.

7. The semiconductor transistor structure of claim 1, wherein the gate dielectric further comprises a third part between a top surface of the dielectric structure and a bottom surface of the gate electrode.

8. The semiconductor transistor of claim 1, wherein the channel further comprises (i) a bottom surface of the first part in contact with the first source/drain contact and (ii) a bottom surface of the second part in contact with the first source/drain contact.

9. The semiconductor transistor structure of claim 1, further comprising:
a first source/drain contact of a second transistor formed above a layer of dielectric material that is formed above the first and the second parts of the second source/drain contact;
a dielectric structure of the second transistor formed on top of the first source/drain contact of the second transistor;
a gate electrode of the second transistor formed on top of the dielectric structure of the second transistor;
a gate dielectric of the second transistor comprising a first part formed vertically along at least a first sidewall of the gate electrode of the second transistor and a second part formed vertically along at least a second sidewall of the gate electrode of the second transistor;
a channel of the second transistor comprising a first part formed on a surface of the first part of the gate dielectric of the second transistor and a second part formed on a surface of the second part of the gate dielectric of the second transistor; and
a second source/drain contact of the second transistor comprising a first part on top of the first part of the channel of the second transistor and a second part on top of the second part of the channel of the second transistor.

10. The semiconductor transistor structure of claim 9, wherein the layer of dielectric material is formed above the first and the second parts of the second source/drain contact and below the second transistor, the layer of dielectric material comprising a routing layer comprising one or more metal connections for routing electrical signals to one or more of the transistor or the second transistor.

11. A method of forming a transistor structure, the method comprising:
forming a first source/drain contact of a transistor;
forming a dielectric structure on top of the first source/drain contact;
forming a gate electrode of the transistor on top of the dielectric structure;
forming a first part of a gate dielectric vertically along at least a first sidewall of the gate electrode;
forming a second part of the gate dielectric vertically along at least a second sidewall of the gate electrode;
forming a first part of a channel of the transistor on a surface of the first part of the gate dielectric;
forming a second part of the channel of the transistor on a surface of the second part of the gate dielectric; and
forming a first part of a second source/gate contact of the transistor on top of the first part of the channel;
forming a second part of the second source/gate contact of the transistor on top of the second part of the channel.

12. The method of claim 11, wherein forming the gate electrode includes vertically extending the first part of the gate electrode above the dielectric structure, a height of the gate electrode being greater than each one of a width and a thickness of the gate electrode.

13. The method of claim 11, wherein forming the first part of the channel and the second part of the channel includes forming a respective conductive oxide material (i) abutting the gate dielectric and (ii) extending vertically along the gate electrode.

14. The method of claim 11, wherein forming the first part of the gate dielectric further includes extending the first part of the gate dielectric along a first sidewall of the dielectric structure, and wherein forming the second part of the gate dielectric further includes extending the second part of the gate dielectric along a second sidewall of the dielectric structure.

15. The method of claim 11, further comprising forming a gate contact on top of the gate electrode, the gate contact formed at a same height as the first and second parts of the second source/drain contacts.

16. The method of claim 11, further comprising forming a dielectric material layer insulating the first source/drain contact from a substrate beneath the first source/drain contact.

17. The method of claim 11, further comprising forming a third part of the gate dielectric between a top surface of the dielectric structure and a bottom surface of the gate electrode.

18. The method of claim 11, further comprising:
forming a bottom surface of the first part of the channel in contact with the first source/drain contact; and
forming a bottom surface of the second part of the channel in contact with the first source/drain contact.

19. The method of claim 11, further comprising:
forming a first source/drain contact of a second transistor above the first and second parts of the second source/drain contact;
forming a dielectric structure of the second transistor on top of the first source/drain contact of the second transistor;
forming a gate electrode of the second transistor on top of the dielectric structure of the second transistor;
forming a first part of a gate dielectric of the second transistor along at least a first sidewall of the gate electrode of the second transistor;
forming a second part of the gate dielectric of the second transistor along at least a second sidewall of the gate electrode of the second transistor;
forming a first part of a channel of the second transistor on a surface of the first part of the gate dielectric of the second transistor;
forming a second part of the channel of the second transistor on a surface of the second part of the gate dielectric of the second transistor;
forming a first part of the second source/gate contact of the second transistor on top of the first part of the channel of the second transistor; and
forming a second part of the second source/gate contact of the second transistor on top of the second part of the channel of the second transistor.

20. The method of claim 19, further comprising forming, above the first and the second parts of the second source/drain contact and below the second transistor, a routing layer comprising one or more metal connections for routing electrical signals to one or more of the transistor or the second transistor.
